(19) United States
(12) Patent Application Publication
(10) Pub. No.: US 2025/0098463 A1
(43) Pub. Date: Mar. 20, 2025

(54) DISPLAY PANEL AND DISPLAY APPARATUS

(71) Applicant: Wuhan Tianma Microelectronics Co., Ltd. Shanghai Branch, Shanghai (CN)

(72) Inventors: Lin ZHANG, Shanghai (CN); Xian CHEN, Shanghai (CN); Yu XIN, Shanghai (CN)

(21) Appl. No.: 18/969,315

(22) Filed: Dec. 5, 2024

(30) Foreign Application Priority Data
Sep. 6, 2024 (CN) 202411252987.6

(51) Int. Cl. H10K 59/131; H10K 59/122; H10K 59/35

(52) U.S. Cl. CPC H10K 59/131; H10K 59/122; H10K 59/353

(57) ABSTRACT

A display panel includes: a main display area, a peripheral wiring area, a substrate, an array layer, a pixel definition layer and light-emitting devices. The array layer includes pixel driving circuits located in the main display area. The pixel definition layer includes openings that include first openings and second openings. The first openings are located in the main display area, and the second openings are located in the peripheral wiring area. The light-emitting devices include first light-emitting devices and second light-emitting devices. The first light-emitting devices are in one-to-one correspondence with the first openings, and the second light-emitting devices are in one-to-one correspondence with the second openings. The light-emitting device includes an anode. The anode of the first light-emitting device is electrically connected to the pixel driving circuit corresponding thereto, and the anode of the second light-emitting device is connected to the anode of the first light-emitting device adjacent thereto.

### CROSS-REFERENCE TO RELATED APPLICATION

The present application claims priority to Chinese Patent Application No. 202411252987.6, filed on Sep. 6, 2024, the content of which is incorporated herein by reference in its entirety.

### TECHNICAL FIELD

The present disclosure relates to the field of display technology and, in particular, to a display panel and a display apparatus.

### BACKGROUND

Organic Light-emitting Diode (OLED) displays are increasingly used in various portable electronic devices because of their thinness, power saving and other characteristics.

Meanwhile, users have also put forward higher requirements for display quality of the display screen. For example, users prefer display screens with high Pixel per Inch (PPI) and narrow frame. Therefore, how to achieve high PPI and narrow frame design on the display screen has become one of the problems that those skilled in the art need to solve urgently.

### SUMMARY

An aspect of the present disclosure provides a display panel. The display panel includes a main display area; a peripheral wiring area surrounding the main display area; a substrate; an array layer; a pixel definition layer; and light-emitting devices. The array layer is located on a side of the substrate, and includes a plurality of pixel driving circuits located in the main display area. The pixel definition layer is located on a side of the array layer away from the substrate, and includes a plurality of openings. The plurality of openings includes first openings and second openings. The first openings are located in the main display area, and the second openings are located in the peripheral wiring area. The light-emitting devices include first light-emitting devices and second light-emitting devices. The first light-emitting devices are in one-to-one correspondence with the first openings, and the first light-emitting devices are located in the first openings corresponding thereto. The second light-emitting devices are in one-to-one correspondence with the second openings, and the second light-emitting devices are located in the second openings corresponding thereto. One of the light-emitting devices includes an anode, the anode of one of the first light-emitting devices is electrically connected to the pixel driving circuit corresponding thereto, and the anode of one of the second light-emitting devices is connected to the anode of the first light-emitting device adjacent thereto.

Another aspect of the present disclosure provides a display apparatus. The display apparatus includes a display panel. The display panel includes a main display area; a peripheral wiring area surrounding the main display area; a substrate; an array layer; a pixel definition layer; and light-emitting devices. The array layer is located on a side of the substrate, and includes a plurality of pixel driving circuits located in the main display area. The pixel definition layer is located on a side of the array layer away from the substrate, and includes a plurality of openings. The plurality of openings includes first openings and second openings. The first openings are located in the main display area, and the second openings are located in the peripheral wiring area. The light-emitting devices include first light-emitting devices and second light-emitting devices. The first light-emitting devices are in one-to-one correspondence with the first openings, and the first light-emitting devices are located in the first openings corresponding thereto. The second light-emitting devices are in one-to-one correspondence with the second openings, and the second light-emitting devices are located in the second openings corresponding thereto. One of the light-emitting devices includes an anode, the anode of one of the first light-emitting devices is electrically connected to the pixel driving circuit corresponding thereto, and the anode of one of the second light-emitting devices is connected to the anode of the first light-emitting device adjacent thereto.

### BRIEF DESCRIPTION OF DRAWINGS

The drawings, which are incorporated in and constitute a part of the specification, show embodiments in accordance with the present disclosure and, in conjunction with the specification, serve to explain the principles of the present disclosure.

In order to more clearly explain the embodiments of the present disclosure or the technical solution in the related art, the drawings to be used in the description of the embodiments or the related art will be briefly described below. The drawings in the following description are some embodiments of the present disclosure. For those skilled in the art, other drawings may also be obtained based on these drawings.

FIG. 1 is a schematic plan view of a display panel according to some embodiments of the present disclosure;

FIG. 2 is an enlarged schematic diagram of a portion A of the display panel shown in FIG. 1 according to some embodiments of the present disclosure;

FIG. 3 is a cross-sectional view of the display panel along the line B-B′ of FIG. 2 according to some embodiments of the present disclosure;

FIG. 4 is an enlarged schematic diagram of a portion C of the display panel shown in FIG. 1 according to some embodiments of the present disclosure;

FIG. 5 is an enlarged schematic diagram of a portion D of the display panel shown in FIG. 1 according to some embodiments of the present disclosure;

FIG. 6 is an enlarged schematic diagram of a portion C of the display panel shown in FIG. 1 according to some embodiments of the present disclosure;

FIG. 7 is an enlarged schematic diagram of a portion E of the display panel shown in FIG. 1 according to some embodiments of the present disclosure;

FIG. 8 is an enlarged schematic diagram of a portion C of the display panel shown in FIG. 1 according to some embodiments of the present disclosure;

FIG. 9 is an enlarged schematic diagram of a portion E of the display panel shown in FIG. 1 according to some embodiments of the present disclosure;

FIG. 10 is an enlarged schematic diagram of a portion A of the display panel shown in FIG. 1 according to some embodiments of the present disclosure;

FIG. 11 is an enlarged schematic diagram of a portion D of the display panel shown in FIG. 1 according to some embodiments of the present disclosure;

FIG. 12 is an enlarged schematic diagram of a portion C of the display panel shown in FIG. 1 according to some embodiments of the present disclosure;

FIG. 13 is an enlarged schematic diagram of a portion E of the display panel shown in FIG. 1 according to some embodiments of the present disclosure;

FIG. 14 is an enlarged schematic diagram of a portion C of the display panel shown in FIG. 1 according to some embodiments of the present disclosure;

FIG. 15 is an enlarged schematic diagram of a portion C of the display panel shown in FIG. 1 according to some embodiments of the present disclosure;

FIG. 16 is an enlarged schematic diagram of a portion E of the display panel shown in FIG. 1 according to some embodiments of the present disclosure;

FIG. 17 is an enlarged schematic diagram of a portion E of the display panel shown in FIG. 1 according to some embodiments of the present disclosure;

FIG. 18 is an enlarged schematic diagram of a portion C of the display panel shown in FIG. 1 according to some embodiments of the present disclosure;

FIG. 19 is an enlarged schematic diagram of a portion E of the display panel shown in FIG. 1 according to some embodiments of the present disclosure;

FIG. 20 is an enlarged schematic diagram of a portion A of the display panel shown in FIG. 1 according to some embodiments of the present disclosure;

FIG. 21 is an enlarged schematic diagram of a portion A of the display panel shown in FIG. 1 according to some embodiments of the present disclosure; and

FIG. 22 is a schematic plan view of a display apparatus according to some embodiments of the present disclosure.

### DESCRIPTION OF EMBODIMENTS

In order to more clearly illustrate objectives, technical solutions, and advantages of the embodiments of the present disclosure, the technical solutions of the present disclosure will be further described below. It should be noted that, in the absence of conflict, the embodiments of the present disclosure and the features in the embodiments can be combined with each other.

In the following description, many specific details are set forth to facilitate a full understanding of the present disclosure, but the present disclosure may also be implemented in other ways different from those described herein. The described embodiments are merely part of the embodiments of the present disclosure rather than all of the embodiments.

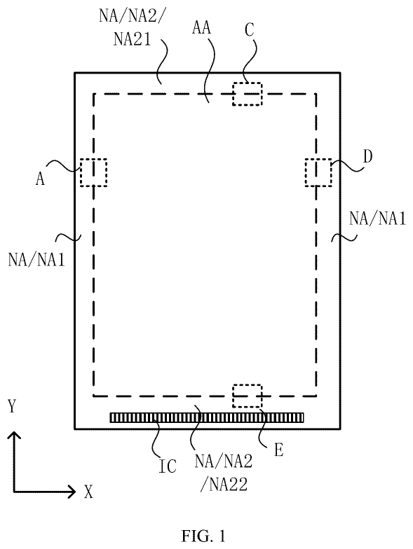

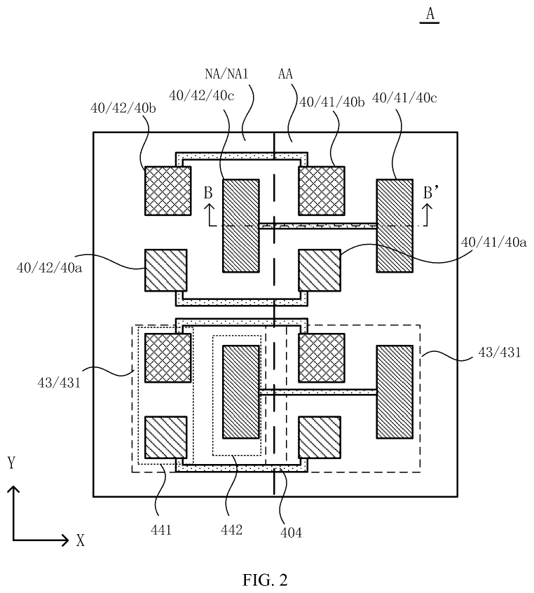

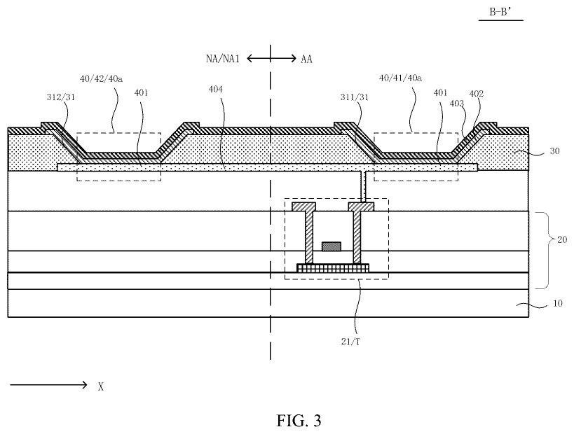

FIG. 1 is a schematic plan view of a display panel according to some embodiments of the present disclosure, FIG. 2 is an enlarged schematic diagram of a portion A of the display panel shown in FIG. 1 according to some embodiments of the present disclosure, and FIG. 3 is a cross-sectional view of the display panel along the line B-B′ of FIG. 2 according to some embodiments of the present disclosure. Referring to FIG. 1 to FIG. 3, the present disclosure provides a display panel, and the display panel includes: a main display area AA and a peripheral wiring area NA surrounding the main display area AA; a substrate 10; an array layer 20; a pixel definition layer 30; and light-emitting devices 40. The array layer 20 is located on a side of the substrate 10, and includes a plurality of pixel driving circuits 21. The pixel driving circuits 21 are located in the main display area AA. The pixel definition layer 30 is located on a side of the array layer 20 away from the substrate 10, and includes a plurality of openings 31. The openings 31 include first openings 311 and second openings 312, the first openings 311 are located in the main display area AA, and the second openings 312 are located in the peripheral wiring area NA. The light-emitting devices 40 include first light-emitting devices 41 and second light-emitting devices 42, the first light-emitting devices 41 are in one-to-one correspondence with the first openings 311, each of the first light-emitting devices 41 is located in the first opening 311 corresponding thereto, the second light-emitting devices 42 are in one-to-one correspondence with the second openings 312, and each of the second light-emitting devices 42 is located in the second opening 312 corresponding thereto. Each of the light-emitting devices 40 includes an anode 401, the anode 401 of each of the first light-emitting devices 41 is electrically connected to the pixel driving circuit 21 corresponding thereto, and the anode 401 of each of the second light-emitting devices 42 is connected to the anode 401 of the first light-emitting device 41 adjacent thereto.

In an embodiment, the display panel according to the present disclosure includes the main display area AA and the peripheral wiring area NA surrounding the main display area AA. The main display area AA is configured to display images, and the peripheral wiring area NA is configured to arrange circuit elements such as scan driving circuits and driving chips.

The display panel includes the substrate 10. The substrate 10 may be a rigid substrate, and the material of the substrate 10 is glass. The substrate 10 may further be a flexible substrate, and the material of the substrate 10 is polyimide (PI), polycarbonate (PC) or polyethylene terephthalate (PET). The substrate 10 is configured to support and protect the film layer formed thereon.

The display panel further includes the array layer 20 and the pixel definition layer 30. The array layer 20 is located on a side of the substrate 10, and the pixel definition layer 30 is located on the side of the array layer 20 away from the substrate 10. The pixel definition layer 30 includes a plurality of openings 31, the pixel definition layer 30 defines a light-emitting area through the openings 31, and the light-emitting area is configured to set the light-emitting devices 40. Each of the light-emitting device 40 includes the anode 401, an organic light-emitting layer 402 and a cathode 403, and the organic light-emitting layer 402 is located between the anode 401 and the cathode 403. The anode 401 is an image structure insulated from each other. The cathodes 403 of the light-emitting devices 40 are connected to each other.

The array layer 20 includes a plurality of pixel driving circuits 21, and the pixel driving circuits 21 are located in the main display area AA. The openings 31 include first openings 311, and the first openings 311 are located in the main display area AA. The light-emitting devices 40 include first light-emitting devices 41. The first light-emitting devices 41 are in one-to-one correspondence with the first openings 311, and each of the first light-emitting devices 41 is located in the first opening 311 corresponding thereto. The anode 401 of each of the first light-emitting devices 41 is electrically connected to the pixel driving circuit 21 corresponding thereto, and the pixel driving circuits 21 are configured to drive the first light-emitting devices 41 electrically connected thereto to emit light.

It should be noted that FIG. 3 only exemplarily shows that the pixel driving circuit 21 includes a transistor T. Those skilled in the art may set the specific circuit structure of the pixel driving circuit 21 according to actual conditions. For example, the circuit structure may be a 2T1C (two transistors and one capacitor), 7T1C, 8T1C or other circuits in the related art, which are not limited thereto in the present disclosure.

In the display panel according to the embodiments of the present disclosure, the openings 31 in the pixel definition layer 30 further include second openings 312, and the second openings 312 are located in the peripheral wiring area NA. The light-emitting devices 40 further include second light-emitting devices 42. The second light-emitting devices 42 are in one-to-one correspondence with the second openings 312, and each of the second light-emitting devices 42 is located in the second opening 312 corresponding thereto. That is, the second light-emitting devices 42 are provided in the peripheral wiring area NA, and the anode 401 of each of the second light-emitting devices 42 is connected to the anode 401 of the first light-emitting device 41 adjacent thereto, so that the pixel driving circuit 21 electrically connected to the anode 401 of the first light-emitting device 41 adjacent thereto can simultaneously drive the second light-emitting device 42 and the first light-emitting device 41 adjacent thereto to emit light, thereby achieving the light emission of the second light-emitting devices 42 located in the peripheral wiring area NA, and reducing the dark area of the peripheral wiring area NA, which is conducive to achieving high PPI and narrow frame of the display panel, and the anode 401 of the second light-emitting device 42 can shield the wiring of the peripheral wiring area NA, thereby improving the display effect of the display panel.

Meanwhile, there is no need to additionally provide a pixel driving circuit 21 in the portion, located in the peripheral wiring area NA, of the array layer 20, which will not affect the arrangement of the original circuit elements in the peripheral wiring area NA, and can effectively reduce the number of the provided pixel driving circuits 21, thereby facilitating the reduction of the area of the wiring area NA and the realization of the narrow frame of the display panel.

It should be noted that FIG. 2 exemplarily shows an arrangement of the light-emitting devices 40 in the display panel. In some embodiments of the present disclosure, other arrangements of the light-emitting devices 40 in the display panel may also be adopted, which will not be elaborated in the present disclosure.

It should be noted that FIG. 2 exemplarily shows that the vertical projection pattern of the light-emitting device 40 on the plane of the substrate 10 is rectangle. In some embodiments of the present disclosure, the vertical projection pattern of the light-emitting device 40 on the plane of the substrate 10 may also be other shapes, which will not be elaborated in the present disclosure.

Referring to FIG. 1 to FIG. 3, in some embodiments of the present disclosure, the light-emitting devices 40 include first color light-emitting devices 40a, second color light-emitting devices 40b, and third color light-emitting devices 40c. The brightness of the first color light-emitting devices 40a is greater than the brightness of the second color light-emitting devices 40b, and the brightness of the second color light-emitting devices 40b is greater than the brightness of the third color light-emitting devices 40c. The anode 401 of each of the second light-emitting devices 42 is connected to the anode 401 of the first light-emitting device 41, with the same light-emitting color, adjacent thereto.

In an embodiment, the light-emitting devices 40 include first color light-emitting devices 40a, second color light-emitting devices 40b, and third color light-emitting devices 40c. The brightness of the first color light-emitting devices 40a is greater than the brightness of the second color light-emitting devices 40b, and the brightness of the second color light-emitting devices 40b is greater than the brightness of the third color light-emitting devices 40c. For example, the first color light-emitting devices 40a are red light-emitting devices, the second color light-emitting devices 40b are green light-emitting devices, and the third color light-emitting devices 40c are blue light-emitting devices. In some embodiments of the present disclosure, the light-emitting devices may also include light-emitting devices of other colors, which will not be elaborated in the present disclosure.

The anode 401 of each of the second light-emitting devices 42 is connected to the anode 401 of the first light-emitting device 41, with the same light-emitting color, adjacent thereto. That is, the anode 401 of the first color light-emitting device 40a located in the peripheral wiring area NA is connected to the anode 401 of the first color light-emitting device 40a located in the main display area AA adjacent thereto. The anode 401 of the second color light-emitting device 40b located in the peripheral wiring area NA is connected to the anode 401 of the second color light-emitting device 40b located in the main display area AA adjacent thereto. The anode 401 of the third color light-emitting device 40c located in the peripheral wiring area NA is connected to the anode 401 of the third color light-emitting device 40c located in the main display area AA adjacent thereto.

The anode 401 of the first color light-emitting device 40a located in the peripheral wiring area NA is connected to the anode 401 of the first color light-emitting device 40a located in the main display area AA adjacent thereto, so that the first color light-emitting device 40a located in the peripheral wiring area NA and the first color light-emitting device 40a located in the main display area AA adjacent thereto can be simultaneously driven to emit light through the same pixel driving circuit 21. Similarly, the anode 401 of the second color light-emitting device 40b located in the peripheral wiring area NA is connected to the anode 401 of the second color light-emitting device 40b located in the main display area AA adjacent thereto, so that the second color light-emitting device 40b located in the peripheral wiring area NA and the second color light-emitting device 40b located in the main display area AA adjacent thereto can be simultaneously driven to emit light through the same pixel driving circuit 21. Similarly, the anode 401 of the third color light-emitting device 40c located in the peripheral wiring area NA is connected to the anode 401 of the third color light-emitting device 40c located in the main display area AA adjacent thereto, so that the third color light-emitting device 40c located in the peripheral wiring area NA and the third color light-emitting device 40c located in the main display area AA adjacent thereto can be simultaneously driven to emit light through the same pixel driving circuit 21. That is, the anode 401 of the light-emitting device 40 located in the peripheral wiring area NA is connected to the anode 401 of the light-emitting device 40 located in the main display area AA adjacent thereto, and the light-emitting colors of the two are the same. That is, the light-emitting device 40 located in the peripheral wiring area NA and the light-emitting device 40 located in the main display area AA adjacent thereto with the same light-emitting color are controlled by the same pixel driving circuit 21.

It should be noted that, in some embodiments of the present disclosure, the anodes 401 of at least part of the second light-emitting devices 42 may also be connected to the anodes 401 of the first light-emitting devices 41 adjacent thereto with different light-emitting colors, so that the second light-emitting devices 42 located in the peripheral wiring area NA and the adjacent first light-emitting devices 41 located in the main display area AA with different light-emitting colors can be simultaneously driven to emit light by the same pixel driving circuit 21, which will not be elaborated in the present disclosure.

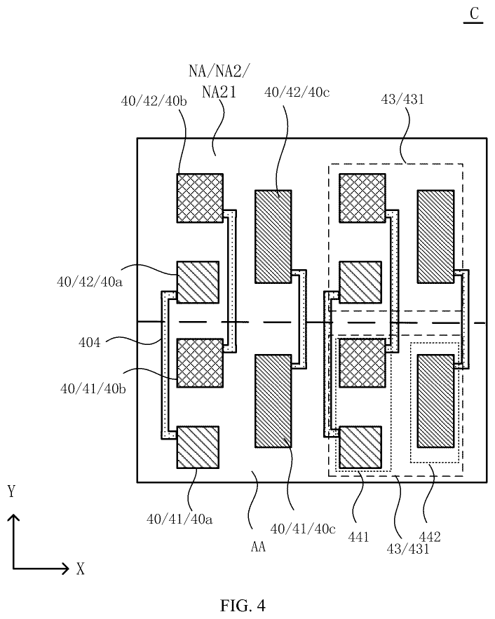

FIG. 4 is an enlarged schematic diagram of a portion C of the display panel shown in FIG. 1. Referring to FIG. 1 to FIG. 4, in some embodiments of the present disclosure, the display panel includes a plurality of light-emitting device groups 43, and each of the light-emitting device groups 43 includes at least one first color light-emitting device 40a, at least one second color light-emitting device 40b, and at least one third color light-emitting device 40c. Each of the light-emitting device groups 43 located in the peripheral display area NA includes at least one of the first color light-emitting device 40a, the second color light-emitting device 40b and the third color light-emitting device 40c. The peripheral wiring area NA includes two first wiring areas NA1 and two second wiring areas NA2. The two first wiring areas NA1 are located on both sides of the main display area AA along a first direction X, respectively, and the two second wiring areas NA2 are located on both sides of the main display area AA along a second direction Y, respectively. In an embodiment, the first direction X intersects with the second direction Y intersect. In some embodiments of the present disclosure, the first direction X is perpendicular to the second direction Y. Each of the first wiring areas NA1 includes at least one column of the light-emitting device groups 43 arranged along the second direction Y. Each of the second wiring areas NA2 includes at least one row of the light-emitting device groups 43 arranged along the first direction X.

In an embodiment, the display panel includes a plurality of light-emitting device groups 43, and each of the light-emitting device groups 43 includes at least one first color light-emitting device 40a, at least one second color light-emitting device 40b, and at least one third color light-emitting device 40c.

It should be noted that FIG. 2 and FIG. 4, for example, show that each of the light-emitting device groups 43 includes one first color light-emitting device 40a, one second color light-emitting device 40b and one third color light-emitting device 40c. The first color light-emitting device 40a is a red light-emitting device, the second color light-emitting device 40b is a green light-emitting device, and the third color light-emitting device 40c is a blue light-emitting device. In some embodiments of the present disclosure, each of the light-emitting device groups 43 may also include other numbers of first color light-emitting devices 40a, second color light-emitting devices 40b and third color light-emitting devices 40c, and other arrangements of the first color light-emitting devices 40a, second color light-emitting devices 40b and third color light-emitting devices 40c in the light-emitting device groups 43 may also be adopted, which will not be elaborated in the present disclosure.

The peripheral wiring area NA includes two first wiring areas NA1. The two first wiring areas NA1 are located on both sides of the main display area AA along the first direction X, respectively, and each of the first wiring area NA1 includes at least one column of light-emitting device groups 43 arranged along the second direction Y. The peripheral wiring area NA further includes two second wiring areas NA2. The two second wiring areas NA2 are located on both sides of the main display area AA along the second direction Y, respectively, and the second wiring area NA2 includes at least one row of light-emitting device groups 43 arranged along the first direction X. The light-emitting device group 43 located in the peripheral display area NA may include at least two of the first color light-emitting device 40a, the second color light-emitting device 40b, and the third color light-emitting device 40c. In some embodiments of the present disclosure, the light-emitting device group 43 located in the peripheral display area NA may simultaneously include the first color light-emitting device 40a, the second color light-emitting device 40b, and the third color light-emitting device 40c. Thus the light-emitting device groups 43 arranged in the peripheral wiring area NA surround the main display area AA, so as to avoid that only the light-emitting devices 40 of a single color are arranged in the peripheral wiring area NA and on one side of the main display area AA, thereby effectively alleviating the color deviation and facilitating improving the display effect of the peripheral wiring area NA.

It should be noted that, in some embodiments of the present disclosure, the light-emitting device group 43 located in the peripheral display area NA may also include only one of the first color light-emitting device 40a, the second color light-emitting device 40b and the third color light-emitting device 40c.

For example, when there is a problem of the green edge of the display panel during display, only the first color light-emitting device 40a may be provided in the corresponding light-emitting device group 43 in the peripheral display area NA. That is, only the red light-emitting device is provided in the corresponding light-emitting device group 43 in the peripheral display area NA, thereby alleviating the problem of the green edge of the display panel during display.

Referring to FIG. 1 to FIG. 3, in some embodiments of the present disclosure, the light-emitting device groups 43 includes first light-emitting device groups 431, and the first light-emitting device groups 431 include first light-emitting device sub-group 441 and second light-emitting device sub-group 442 arranged along the first direction X. Each of the first light-emitting device sub-groups 441 includes one first color light-emitting device 40a and one second color light-emitting device 40b arranged along the second direction Y, and each of the second light-emitting device sub-groups 442 includes one third color light-emitting device 40c. The light-emitting device groups 43 located in the main display area AA and the first wiring area NA1 are the first light-emitting device groups 431.

In an embodiment, the light-emitting device groups 43 include the first light-emitting device groups 431, and the first light-emitting device groups 431 include the first light-emitting device sub-groups 441 and the second light-emitting device sub-groups 442 arranged along the first direction X. Each of the first light-emitting device sub-group 441 includes one first color light-emitting device 40a and one second color light-emitting device 40b arranged along the second direction Y, each of the second light-emitting device sub-group 442 includes one third color light-emitting device 40c, and the light-emitting device groups 43 located in the first wiring area NA1 are the first light-emitting device groups 431, so that in a column of the first light-emitting device sub-groups 441 arranged along the second direction Y in the first wiring area NA1, the first color light-emitting devices 40a and the second color light-emitting devices 40b are alternately provided.

The first color light-emitting devices 40a are red light-emitting devices, and the second color light-emitting devices 40b are green light-emitting devices. The brightness of the first color light-emitting devices 40a and the second color light-emitting devices 40b is relatively high, so that the first color light-emitting devices 40a arranged individually at the edge may cause a serious problem of the red edge during display, and the second color light-emitting devices 40b arranged individually at the edge may cause a serious problem of the green edge during display. That is, the first color light-emitting devices 40a arranged individually at the edge or the second color light-emitting devices 40b arranged individually at the edge may cause the visual effect issue of colorful edges.

In the first wiring area NA1 located on a side of the main display area AA along the first direction X, when the first light-emitting device sub-group 441 in the first light-emitting device group 431 is located on the side of the second light-emitting device sub-group 442 away from the main display area AA, the first color light-emitting devices 40a and the second color light-emitting devices 40b are staggered in the column of light-emitting devices 40 arranged along the second direction Y located in the first wiring area NA1 and away from the outermost edge of the main display area AA, which can effectively alleviate the visual effect issue of colorful edges.

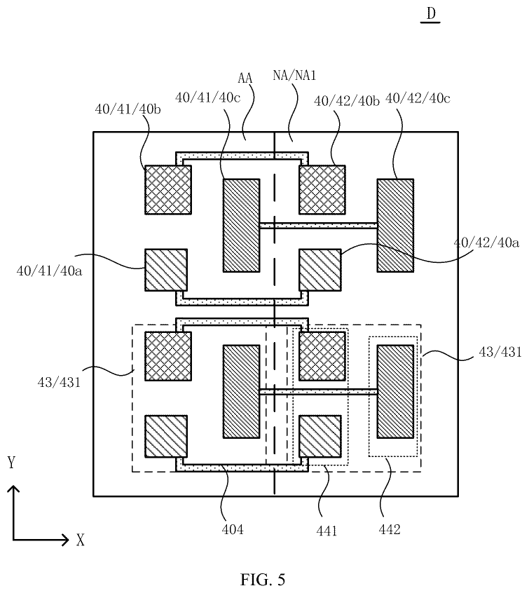

FIG. 5 is an enlarged schematic diagram of a portion D of the display panel shown in FIG. 1. Referring to FIG. 1 and FIG. 5, in the first wiring area NA1 located on the other side of the main display area AA along the first direction X, when the second light-emitting device sub-group 442 in the first light-emitting device group 431 is located on the side of the first light-emitting device sub-group 441 away from the main display area AA, the column of the light-emitting devices 40 arranged along the second direction Y located in the first wiring area NA1 away from the outermost edge of the main display area AA are third color light-emitting devices 40c, and the third color light-emitting devices 40c are blue light-emitting devices. Since the brightness of the third color light-emitting devices 40c is relatively low, the problem of the blue edge during display caused by the light-emitting devices 40, which are third color light-emitting devices 40c and are arranged along the first direction X in the first wiring area NA1 and away from the outermost edge of the main display area AA, is relatively slight, so that the visual effect issue of colorful edges is relatively slight and has little impact on the display effect.

Referring to FIG. 1 and FIG. 4, in some embodiments of the present disclosure, the light-emitting device groups 43 located in the second wiring area NA2 are first light-emitting device groups 431.

In an embodiment, the light-emitting device groups 43 located in the main display area AA are first light-emitting device groups 431, the first light-emitting device groups 431 are provided in the second wiring area NA2, each of the first light-emitting device groups 431 includes a plurality of second light-emitting devices 42. The area in the second wiring area NA2 where the second light-emitting devices 42 are provided can emit light, thereby reducing the dark area of the second wiring area NA2, which is conducive to achieving high PPI and narrow frame of the display panel, and the anode 401 of the second light-emitting device 42 can shield the wiring of the second wiring area NA2, thereby improving the display effect of the display panel.

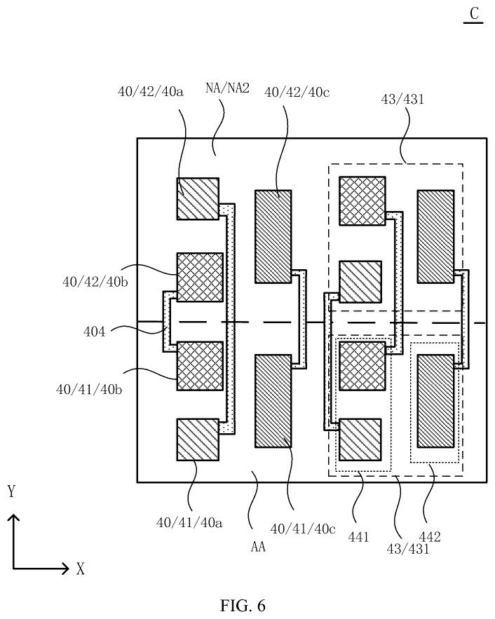

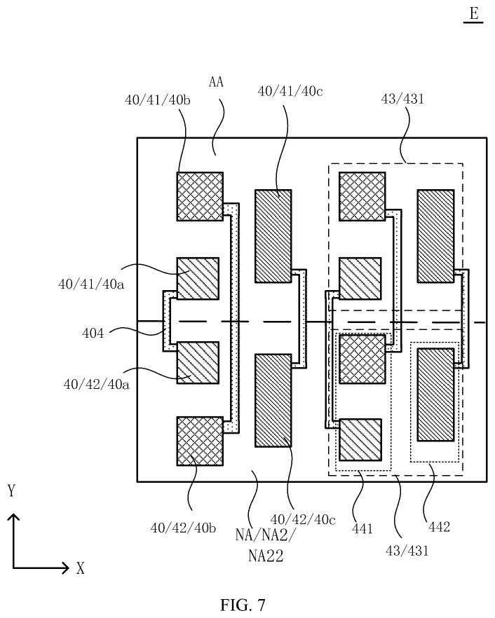

FIG. 6 is an enlarged schematic diagram of a portion C of the display panel shown in FIG. 1, and FIG. 7 is an enlarged schematic diagram of a portion E of the display panel shown in FIG. 1. Referring to FIG. 1, FIG. 6 and FIG. 7, in some embodiments of the present disclosure, in two first light-emitting device sub-groups 441 adjacent to each other along the first direction X in the second wiring area NA2, the first color light-emitting devices 40a and the second color light-emitting devices 40b are staggered.

In an embodiment, the first color light-emitting devices 40a are red light-emitting devices, and the second color light-emitting devices 40b are green light-emitting devices. The brightness of the first color light-emitting devices 40a and the second color light-emitting devices 40b is relatively high, so that the first color light-emitting devices 40a arranged individually at the edge may cause a serious problem of the red edge during display, and the second color light-emitting devices 40b arranged individually at the edge may cause a serious problem of the green edge during display. That is, the first color light-emitting devices 40a arranged individually at the edge or the second color light-emitting devices 40b arranged individually at the edge may cause the visual effect issue of colorful edges.

In two adjacent first light-emitting device sub-groups 441 along the first direction X in the second wiring area NA2, the first color light-emitting devices 40a and the second color light-emitting devices 40b are staggered, and in the row of light-emitting devices 40 arranged along the first direction X in the second wiring area NA2 away from the outermost edge of the main display area AA, the first color light-emitting devices 40a and the second color light-emitting devices 40b are staggered, thereby avoiding the first color light-emitting devices 40a arranged individually or the second color light-emitting devices 40b arranged individually being formed at the outermost edge of the second wiring area NA2 away from the main area AA, which can effectively alleviate the visual effect issue of colorful edges.

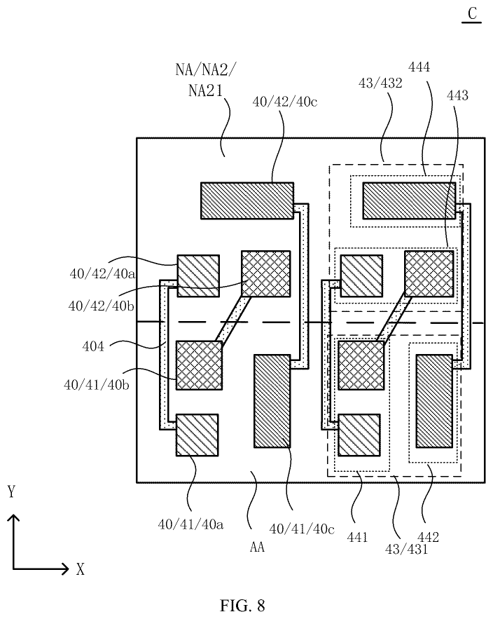

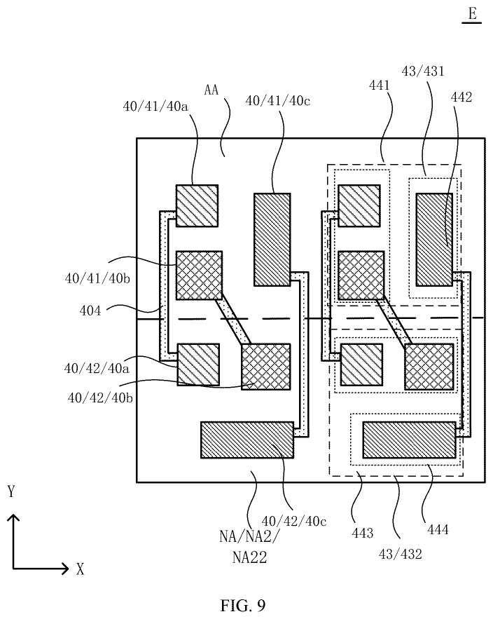

FIG. 8 is an enlarged schematic diagram of a portion C of the display panel shown in FIG. 1, and FIG. 9 is an enlarged schematic diagram of a portion E of the display panel shown in FIG. 1. Referring to FIG. 1, FIG. 8 and FIG. 9, in some embodiments of the present disclosure, the light-emitting device groups 43 include second light-emitting device groups 432, and the second light-emitting device groups 432 include third light-emitting device sub-group 443 and fourth light-emitting device sub-group 444 arranged along the second direction Y. Each of the third light-emitting device sub-group 443 includes one first color light-emitting device 40a and one second color light-emitting device 40b arranged along the first direction X, and each of the fourth light-emitting device sub-group 444 includes one third color light-emitting device 40c. The light-emitting device groups 43 located in the second wiring area NA2 are the second light-emitting device groups 432, and in the second light-emitting device groups 432 located in the second wiring area NA2, the fourth light-emitting device sub-groups 444 are located on the side of the third light-emitting device sub-groups 443 away from the main display area AA.

In an embodiment, the light-emitting device groups 43 located in the second wiring area NA2 are the second light-emitting device groups 432. The second light-emitting device groups 432 include third light-emitting device sub-group 443 and fourth light-emitting device sub-groups 444 arranged along the second direction Y. Each of the third light-emitting device sub-groups 443 includes one first color light-emitting device 40a and one second color light-emitting device 40b arranged along the first direction X. The first color light-emitting device 40a is the red light-emitting device, and the second color light-emitting device 40b is the green light-emitting device. Each of the fourth light-emitting device sub-groups 444 includes one third color light-emitting device 40c, and the third color light-emitting device 40c is the blue light-emitting device. In the second light-emitting device groups 432 located in the second wiring area NA2, the fourth light-emitting device sub-groups 444 are located on the side of the third light-emitting device sub-groups 443 away from the main display area AA, so that the row of the light-emitting devices 40 arranged along the first direction X located in the second wiring area NA2 away from the outermost edge of the main display area AA are third color light-emitting devices 40c. Since the brightness of the third color light-emitting devices 40c is relatively low, the problem of the blue edge during display caused by the light-emitting devices 40, which are third color light-emitting devices 40c and are arranged along the first direction X in the second wiring area NA2 and away from the outermost edge of the main display area AA, is relatively slight, so that the visual effect issue of colorful edges is relatively slight and has little impact on the display effect.

In some embodiments of the present disclosure, the light-emitting device groups 43 located in the second wiring area NA2 are the second light-emitting device groups 432. In the second light-emitting device groups 432 located in the second wiring area NA2, when the fourth sub-light-emitting device groups 444 are located on the side of the third sub-light-emitting device group 443 away from the main display area AA, the third color light-emitting devices 40c in the fourth sub-light-emitting device groups 444 and the third color light-emitting devices 40c in the adjacent first light-emitting device groups 431 along the second direction Y are located on the same side, thereby facilitating the connection of the anodes of the two.

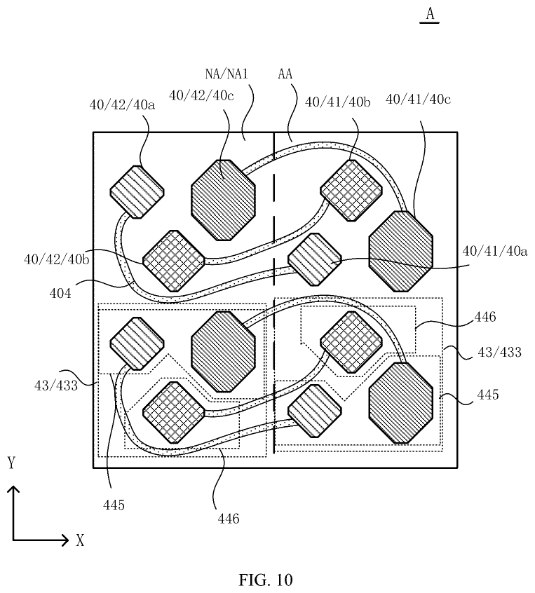

FIG. 10 is an enlarged schematic diagram of a portion A of the display panel shown in FIG. 1. Referring to FIG. 1 and FIG. 10, in some embodiments of the present disclosure, the light-emitting device groups 43 include third light-emitting device groups 433, and the third light-emitting device group 433s include fifth light-emitting device sub-group 445 and sixth light-emitting device sub-group 446 arranged along the second direction Y. Each of the fifth light-emitting device sub-groups 445 includes one first color light-emitting device 40a and one third color light-emitting device 40c arranged along the first direction X, and each of the sixth light-emitting device sub-groups 446 includes one second color light-emitting device 40b. The fifth light-emitting device sub-groups 445 and the sixth light-emitting device sub-groups 446 in two adjacent third light-emitting device groups 433 along the first direction X are staggered. The light-emitting device groups 43 located in the main display area AA and the first wiring area NA1 are the third light-emitting device groups 433.

In an embodiment, the light-emitting device groups 43 include third light-emitting device groups 433, and the third light-emitting device groups 433 include fifth light-emitting device sub-groups 445 and sixth light-emitting device sub-groups 446 arranged along the second direction Y. Each of the fifth light-emitting device sub-groups 445 includes one first color light-emitting device 40a and one third color light-emitting device 40c arranged along the first direction X, each of the sixth light-emitting device sub-groups 446 includes one second color light-emitting device 40b, and the light-emitting device groups 43 located in the first wiring area NA1 are the third light-emitting device groups 433, so that in the column of the third light-emitting device groups 433 arranged along the second direction Y in the first wiring area NA1, the first color light-emitting devices 40a and the second color light-emitting devices 40b are staggered.

The first color light-emitting devices 40a are red light-emitting devices, and the second color light-emitting devices 40b are green light-emitting devices. The brightness of the first color light-emitting devices 40a and the second color light-emitting devices 40b is relatively high, thus the first color light-emitting devices 40a arranged individually at the edge may cause a serious problem of the red edge during display, and the second color light-emitting devices 40b arranged individually at the edge may cause a serious problem of the green edge during display. That is, the first color light-emitting devices 40a arranged individually at the edge or the second color light-emitting devices 40b arranged individually at the edge may cause the visual effect issue of colorful edges.

In the first wiring area NA1 located on a side of the main display area AA along the first direction X, when the first color light-emitting devices 40a in the third light-emitting device group 433 is located on the side of the third color light-emitting device 40c away from the main display area AA, the first color light-emitting devices 40a and the second color light-emitting devices 40b are staggered in the light-emitting device 40 located in the first wiring area NA1 away from the outermost edge of the main display area AA, thereby avoiding the first color light-emitting devices 40a arranged individually or the second color light-emitting devices 40b arranged individually being formed at the outermost edge of the second wiring area NA1 away from the outermost edge of the main display area AA, which can effectively alleviate the visual effect issue of colorful edges.

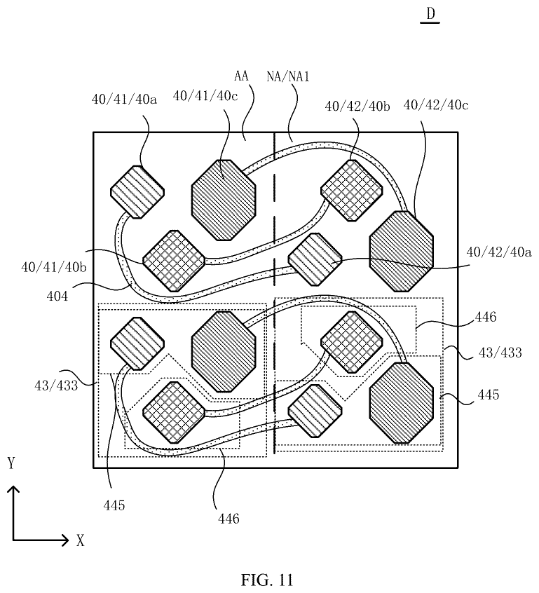

FIG. 11 is an enlarged schematic diagram of a portion D of the display panel shown in FIG. 1. Referring to FIG. 1 and FIG. 11, in the first wiring area NA1 located on the other side of the main display area AA along the first direction X, when the third color light-emitting devices 40c in the third light-emitting device group 433 are located on the side of the first color light-emitting devices 40a away from the main display area AA, the column of the light-emitting devices 40 arranged along the second direction Y and located in the first wiring area NA1 away from the outermost edge of the main display area AA are the third color light-emitting devices 40c, and the third color light-emitting devices 40c are blue light-emitting devices. Since the brightness of the third color light-emitting devices 40c is relatively low, the problem of the blue edge during display caused by the light-emitting devices 40, which are third color light-emitting devices 40c and are arranged along the first direction X in the first wiring area NA1 and away from the outermost edge of the main display area AA, is relatively slight, so that the visual effect issue of colorful edges is relatively slight and has little impact on the display effect.

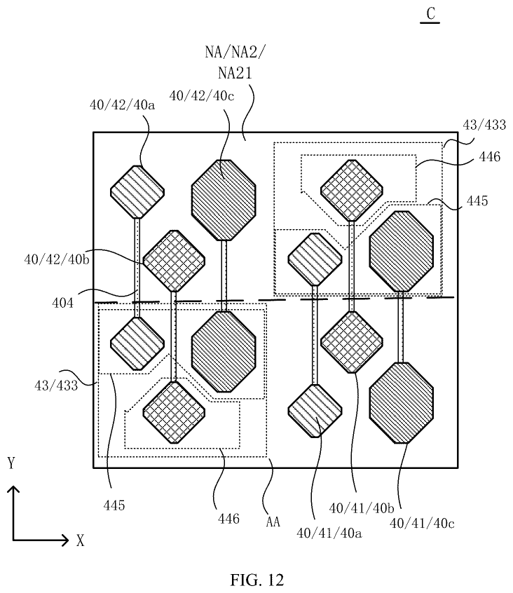

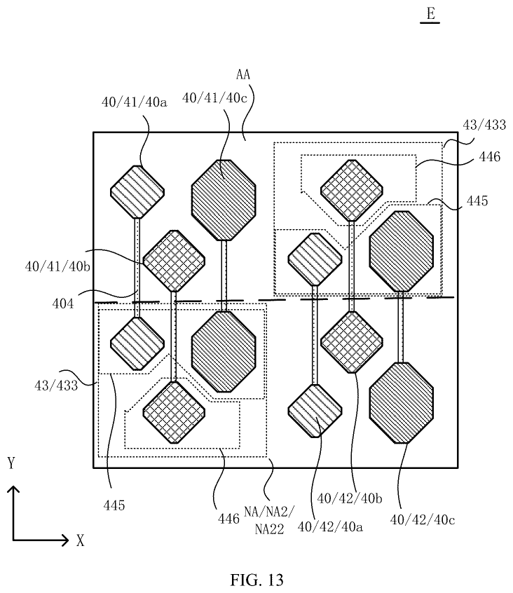

FIG. 12 is an enlarged schematic diagram of a portion C of the display panel shown in FIG. 1, and FIG. 13 is an enlarged schematic diagram of a portion E of the display panel shown in FIG. 1. Referring to FIG. 1, FIG. 12 and FIG. 13, in some embodiments of the present disclosure, the light-emitting device groups 43 located in the second wiring area NA2 are third light-emitting device groups 433.

In an embodiment, the first color light-emitting devices 40a are red light-emitting devices, and the second color light-emitting devices 40b are green light-emitting devices. The brightness of the first color light-emitting devices 40a and the second color light-emitting devices 40b is relatively high, thus the first color light-emitting devices 40a arranged individually at the edge may cause a serious problem of the red edge during display, and the second color light-emitting devices 40b arranged individually at the edge may cause a serious problem of the green edge during display. That is, the first color light-emitting devices 40a arranged individually at the edge or the second color light-emitting devices 40b arranged individually at the edge may cause the visual effect issue of colorful edges.

In the second wiring area NA2, the light-emitting device groups 43 are the third light-emitting device groups 433, and the first color light-emitting devices 40a and the second color light-emitting devices 40b in two adjacent third light-emitting device groups 433 along the first direction X are staggered, so that in the row of light-emitting devices 40 arranged along the first direction X in the second wiring area NA2 away from the outermost edge of the main display area AA, the first color light-emitting devices 40a, the second color light-emitting devices 40b and the third color light-emitting devices 40c are staggered in sequence, thereby avoiding the first color light-emitting devices 40a arranged individually or the second color light-emitting devices 40b arranged individually being formed at the outermost edge of the second wiring area NA2 away from the main area AA, so that the visual effect issue of colorful edges is relatively slight and has little impact on the display effect.

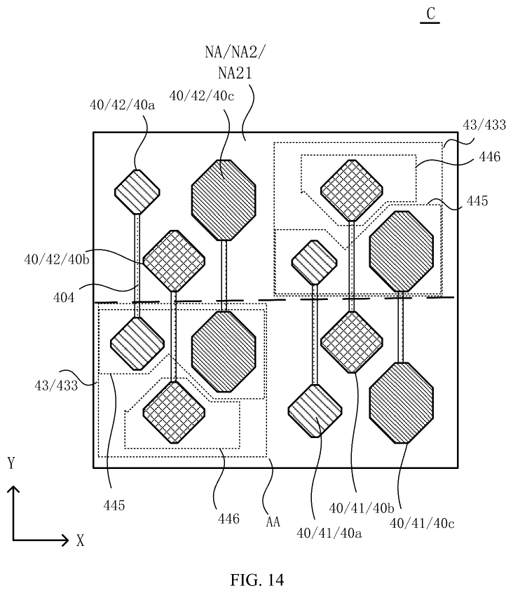

FIG. 14 is an enlarged schematic diagram of a portion C of the display panel shown in FIG. 1. Referring to FIG. 1 and FIG. 14, in some embodiments of the present disclosure, the display panel further includes a driving chip IC. The driving chip IC is located in the peripheral wiring area NA, and along the second direction Y, the driving chip IC is located on a side of the main display area AA, and the pixel driving circuits are electrically connected to the driving chip IC. The second wiring area NA2 includes a first wiring sub-area NA21, and along the second direction Y, the first wiring sub-area NA21 is located on the side of the main display area AA away from the driving chip IC. A vertical projection area, of the first color light-emitting devices 40a located in the first wiring sub-area NA21, on a plane of the substrate 10 is smaller than a vertical projection area, of the first color light-emitting devices 40a located in the main display area AA, on the plane of the substrate 10.

In an embodiment, during display of the display panel, the area corresponding to the side of the main display area away from the driving chip has the problem of appearing red, which affects the display effect of the display panel.

In the embodiment, the second wiring area NA2 includes the first wiring sub-area NA21. Along the second direction Y, the first wiring sub-area NA21 is located on the side of the main display area AA away from the driving chip IC. The vertical projection area, of the first color light-emitting devices 40a located in the first wiring sub-area NA21, on the plane of the substrate 10 is smaller than the vertical projection area, of the first color light-emitting devices 40a located in the main display area AA, on the plane of the substrate 10. That is, the size of the first color light-emitting devices 40a located in the first wiring sub-area NA21 is reduced, and the first color light-emitting devices 40a are red light-emitting devices, so that the size of the red light-emitting area in the first wiring sub-area NA21 is reduced, which is conducive to alleviating the problem of the first wiring sub-area NA21 appearing red and improving the display effect.

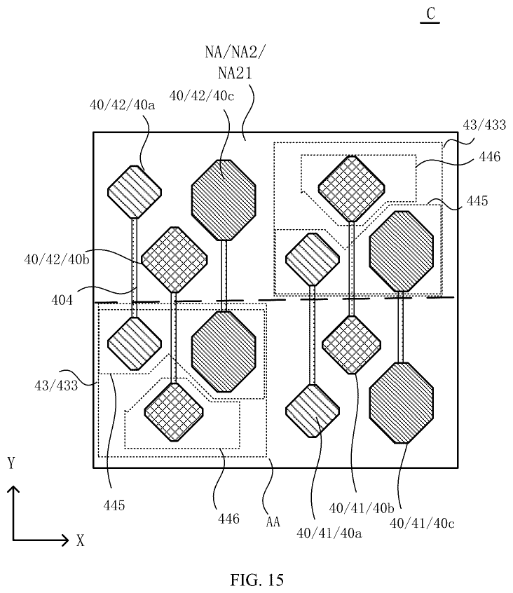

FIG. 15 is an enlarged schematic diagram of a portion C of the display panel shown in FIG. 1. Referring to FIG. 1 and FIG. 15, in some embodiments of the present disclosure, the vertical projection area, of the second color light-emitting devices 40b located in the first wiring sub-area NA21, on the plane of the substrate 10 is greater than the vertical projection area, of the second color light-emitting devices 40b located in the main display area AA, on the plane of the substrate 10.

In an embodiment, the second wiring area NA2 includes the first wiring sub-area NA21. Along the second direction Y, the first sub-wiring area NA21 is located on the side of the main display area AA away from the driving chip IC. The vertical projection area, of the second color light-emitting devices 40b located in the first wiring sub-area NA21, on the plane of the substrate 10 is greater than the vertical projection area, of the second color light-emitting devices 40b located in the main display area AA, on the plane of the substrate 10. That is, the size of the second color light-emitting devices 40b located in the first wiring sub-area NA21 is increased, and the second color light-emitting devices 40b are green light-emitting device, so that the size of the green light-emitting are in the first wiring sub-area NA21 is increased, which is conducive to alleviating the problem of the first wiring sub-area NA21 appearing red and improving the display effect.

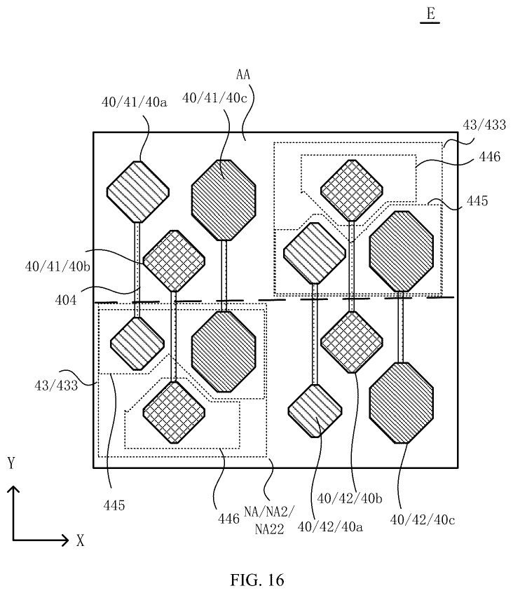

FIG. 16 is an enlarged schematic diagram of a portion E of the display panel shown in FIG. 1. Referring to FIG. 1 and FIG. 16, in some embodiments of the present disclosure, the display panel further includes the driving chip IC. The driving chip IC is located in the peripheral wiring area NA, and along the second direction Y, the driving chip IC is located one one side of the main display area AA, and the pixel driving circuits are electrically connected to the driving chip IC. The second wiring area NA2 includes a second wiring sub-area NA22, and along the second direction Y, the second wiring sub-area NA22 is located between the main display area AA and the driving chip IC. A vertical projection area, of the first color light-emitting devices 40a located in the second wiring sub-area NA2, on a plane of the substrate 10 is greater than a vertical projection area, of the first color light-emitting devices 40a located in the main display area AA, on the plane of the substrate 10.

In an embodiment, during display of the display panel, the area corresponding to the side of the main display area near the driving chip has the problem of appearing green, which affects the display effect of the display panel.

In the embodiment, the second wiring area NA2 includes the second wiring sub-area NA22. Along the second direction Y, the second wiring sub-area NA22 is located between the main display area AA and the driving chip IC. The vertical projection area, of the first color light-emitting devices 40a located in the second wiring sub-area NA22, on the plane of the substrate 10 is greater than the vertical projection area, of the first color light-emitting devices 40a located in the main display area AA, on the plane of the substrate 10. That is, the size of the first color light-emitting devices 40a located in the first wiring sub-area NA21 is increased, and the first color light-emitting devices 40a are red light-emitting devices, so that the size of the red light-emitting area in the first wiring sub-area NA21 is increased, which is conducive to alleviating the problem of the second wiring sub-area NA22 appearing green and improving the display effect.

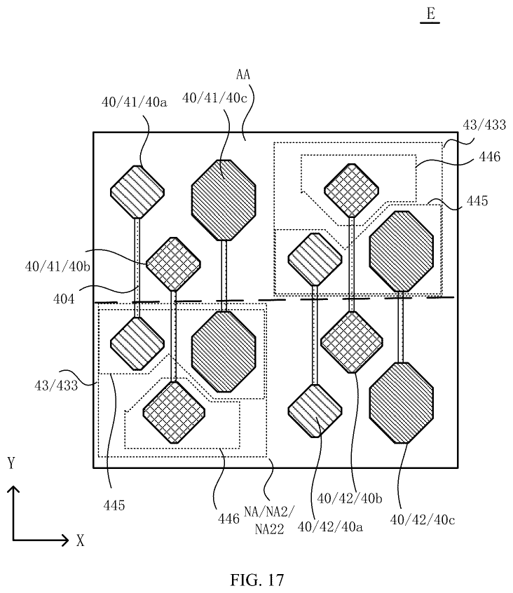

FIG. 17 is an enlarged schematic diagram of a portion E of the display panel shown in FIG. 1. Referring to FIG. 1 and FIG. 17, in some embodiments of the present disclosure, the vertical projection area, of the second color light-emitting devices 40b located in the second wiring sub-area NA22, on the plane of the substrate 10 is smaller than the vertical projection area, of the second color light-emitting devices 40b located in the main display area AA, on the plane of the substrate 10.

In an embodiment, the second wiring area NA2 includes the second wiring sub-area NA22. Along the second direction Y, the second wiring sub-area NA22 is located between the main display area AA and the driving chip IC. The vertical projection area, of the second color light-emitting devices 40b located in the second wiring sub-area NA22, on the plane of the substrate 10 is greater than the vertical projection area, of the second color light-emitting devices 40b located in the main display area AA, on the plane of the substrate 10. That is, the size of the second color light-emitting devices 40b located in the second wiring sub-area NA22 is reduced, and the second color light-emitting devices 40b are green light-emitting devices, so that the size of the green light-emitting area in the second wiring sub-area NA22 is reduced, which is conducive to alleviating the problem of the second wiring sub-area NA22 appearing green and improving the display effect.

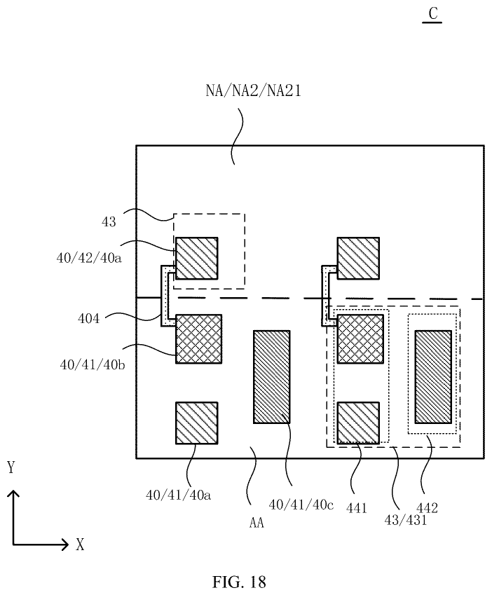

FIG. 18 is an enlarged schematic diagram of a portion C of the display panel shown in FIG. 1. Referring to FIG. 1 and FIG. 18, in some embodiments of the present disclosure, each of the light-emitting device groups 43 located in the peripheral display area NA includes one light-emitting device 40.

In an embodiment, when the row of first light-emitting devices 41 provided in the main display area AA and adjacent to the edge of the main display area AA have the same color, it will cause the problem of colorful edges appearing at the edge during display.

Light-emitting device groups 43 are provided in the peripheral wiring area NA and adjacent to the edge of the main display area AA. Each of the light-emitting device groups 43 includes one light-emitting device 40, and the light-emitting color of the light-emitting device 40 is different from that of the first light-emitting device 41 adjacent thereto, thereby effectively improving the problem of colorful edges appearing at the edge during display.

The anode of the light-emitting device 40 can be directly connected to the anode of the first light-emitting device 41, thereby improving the problem of colorful edges appearing at the edge when the display panel displays various pictures.

The anode of the light-emitting device 40 may also be connected to the anode of the first light-emitting device 41, with the same light-emitting color, adjacent thereto, thereby improving the problem of colorful edges appearing at the edge when the display panel displays white pictures.

For example, referring to FIG. 1 and FIG. 18, the display panel includes light-emitting device groups 43, the light-emitting device groups 43 include first light-emitting device groups 431, and the first light-emitting device groups 431 include first light-emitting device sub-groups 441 and second light-emitting device sub-group 442 arranged along the first direction X. Each of the first light-emitting device sub-groups 441 includes one first color light-emitting device 40a and one second color light-emitting device 40b arranged along the second direction Y, and each of the second light-emitting device sub-groups 442 includes one third color light-emitting device 40c. The first color light-emitting devices 40a are red light-emitting devices, the second color light-emitting devices 40b are green light-emitting devices, and the third color light-emitting devices 40c are blue light-emitting devices. The light-emitting device groups 43 in the main display area AA are the first light-emitting device groups 431. The peripheral wiring area NA includes two second wiring areas NA2. Along the second direction Y, the two second wiring areas NA2 are located on both sides of the main display area AA, respectively. The second wiring area NA2 includes the first wiring sub-area NA21. The row of first light-emitting devices 41 near the first wiring sub-area NA21 in the main display area AA are second color light-emitting devices 40b. That is, the row of first light-emitting devices 41 near the first sub-wiring area NA21 in the main display area AA are green light-emitting devices, which causes the problem of the green edge of the display panel during display. The row of light-emitting device groups 43 is provided in the first wiring sub-area NA21, each of the light-emitting device groups 43 in the first wiring sub-area NA21 includes only one light-emitting device 40, and the light-emitting devices 40 are the first color light-emitting devices 40a. That is, the light-emitting devices 40 are red light-emitting devices, thereby improving the problem of the green edge of the display panel during display.

In some embodiments of the present disclosure, the size of the first color light-emitting devices 40a in the first wiring sub-area NA21 can be provided according to the balance effect to be achieved at the edge of the display panel during display, which will not be elaborated in the present disclosure.

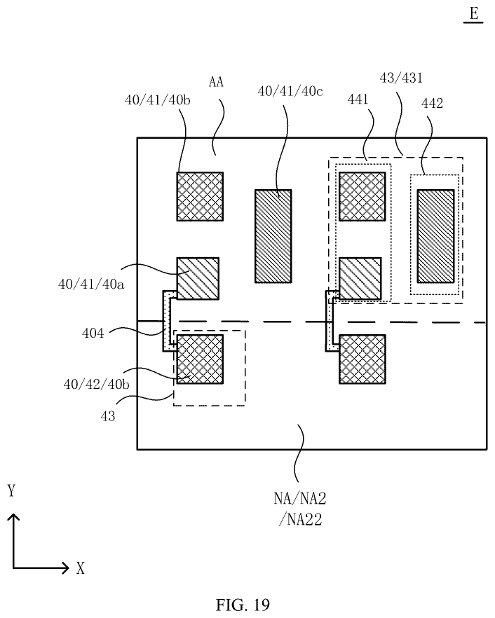

Similarly, referring to FIG. 1 and FIG. 19, FIG. 19 is an enlarged schematic diagram of a portion E of the display panel shown in FIG. 1, the second wiring area NA2 includes the second wiring sub-area NA22, and the row of first light-emitting devices 41 near the second wiring area sub-NA22 in the main display area AA are the first color light-emitting devices 40a. That is, the row of first light-emitting devices 41 near the second wiring sub-area NA22 in the main display area AA are red light-emitting devices, which causes the problem of the red edge of the display panel during display. The row of light-emitting device groups 43 is provided in the second sub-wiring area NA22, each of the light-emitting device groups 43 in the second sub-wiring area NA22 includes only one light-emitting device 40, and the light-emitting devices 40 are the second color light-emitting devices 40b. That is, the light-emitting devices 40 are green light-emitting devices, thereby improving the problem of the red edge of the display panel during display.

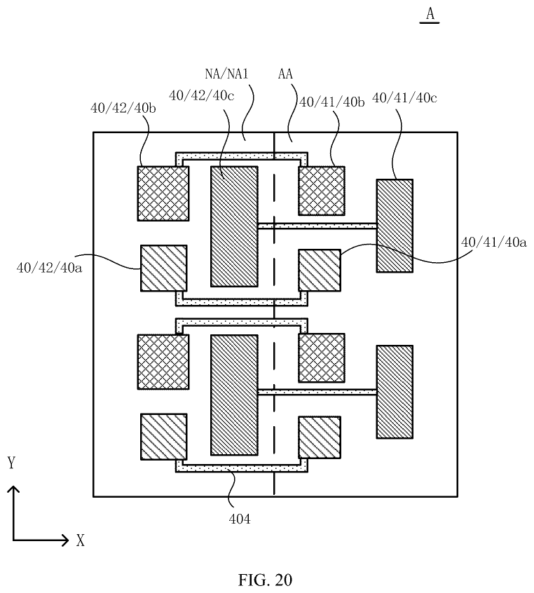

In some embodiments of the present disclosure, the size of the second color light-emitting devices 40b in the second wiring sub-area NA22 can be provided according to the balance effect to be achieved at the edge of the display panel during display, which will not be elaborated in the present disclosure. FIG. 20 is an enlarged schematic diagram of a portion A of the display panel shown in FIG. 1. Referring to FIG. 1 and FIG. 20, in some embodiments of the present disclosure, the vertical projection area of the second light-emitting devices 42 on the plane of the substrate 10 is greater than the vertical projection area of the first light-emitting devices 41 on the plane of the substrate 10.

In an embodiment, the second light-emitting devices 42 are provided in the peripheral wiring area NA, and the anode 401 of the second light-emitting device 42 is connected to the anode 401 of the first light-emitting device 41 adjacent thereto, so that the pixel driving circuit 21 electrically connected to the anode 401 of the first light-emitting device 41 adjacent thereto can simultaneously drive the second light-emitting device 42 and the first light-emitting device 41 adjacent thereto to emit light, thereby achieving the light emission of the second light-emitting device 42 located in the peripheral wiring area NA. The vertical projection area of the second light-emitting devices 42 on the plane of the substrate 10 is greater than the vertical projection area of the first light-emitting device 41 on the plane of the substrate 10. That is, the size of the second light-emitting devices 42 is greater than the size of the first light-emitting device 41. That is, the size of the second light-emitting device 42 in the peripheral wiring area NA is greater, which further reduces the dark area of the peripheral wiring area NA, and is conducive to achieving narrow frame of the display panel and improving the display effect of the display panel.

It should be noted that the description that the vertical projection area of the second light-emitting devices 42 on the plane of the substrate 10 is greater than the vertical projection area of the first light-emitting devices 41 on the plane of the substrate 10 means that among the second light-emitting devices 42 and the first light-emitting devices 41 of the same color, the vertical projection area of the second light-emitting devices 42 on the plane of the substrate 10 is greater than the vertical projection area of the first light-emitting devices 41 on the plane of the substrate 10.

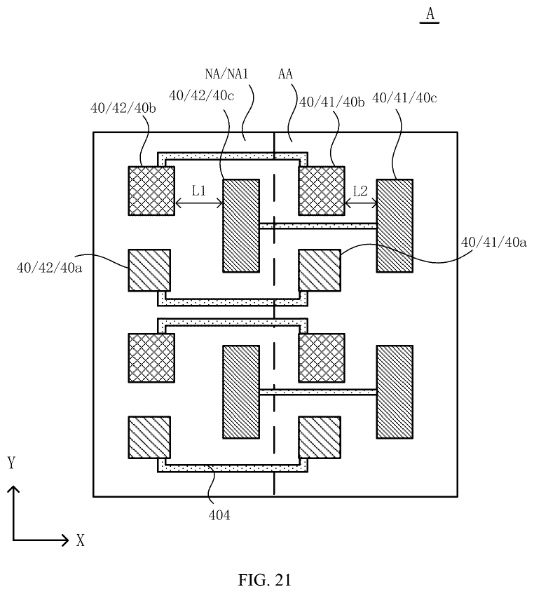

FIG. 21 is an enlarged schematic diagram of a portion A of the display panel shown in FIG. 1. Referring to FIG. 1 and FIG. 21, in some embodiments of the present disclosure, the distance between two adjacent second light-emitting devices 42 is greater than the distance between two adjacent first light-emitting devices 41.

In an embodiment, the second light-emitting devices 42 are provided in the peripheral wiring area NA, and the anode 401 of the second light-emitting device 42 is connected to the anode 401 of the first light-emitting device 41 adjacent thereto, so that the pixel driving circuit 21 electrically connected to the anode 401 of the first light-emitting device 41 adjacent thereto can simultaneously drive the second light-emitting device 42 and the first light-emitting device 41 adjacent thereto to emit light, thereby achieving the light emission of the second light-emitting device 42 located in the peripheral wiring area NA. The distance between two adjacent second light-emitting devices 42 is greater than the distance between two adjacent first light-emitting devices 41, that is, the size of the second light-emitting device 42 is greater than the size of the first light-emitting device 41, that is, the distance between two adjacent second light-emitting devices 42 in the peripheral wiring area NA is relatively large, so that the width of the area, used for providing the second light-emitting devices 42, in the peripheral wiring area NA is relatively large, correspondingly, the width of the area, used for light emission, in the peripheral wiring area NA is increased, which is conducive to achieving narrow frame of the display panel and improving the display effect of the display panel.

For example, referring to FIG. 21, the distance between the second color light-emitting device 40b and the third color light-emitting device 40c adjacent to each other in the first wiring area NA1 is L1, and the distance between the second color light-emitting device 40b and the third color light-emitting device 40c adjacent to each other in the main display area AA is L2. In an embodiment, L1 is greater than L2. It should be noted that FIG. 21 exemplarily shows that the distance between two second light-emitting devices 42 adjacent to each other along the first direction X is greater than the distance between two first light-emitting devices 41 adjacent to each other along the first direction X. In some embodiments of the present disclosure, the distance between two second light-emitting devices 42 adjacent to each other along the second direction Y is greater than the distance between two first light-emitting devices 41 adjacent to each other along the second direction Y, which will not be elaborated in the present disclosure.

Referring to FIG. 1 to FIG. 3, in some embodiments of the present disclosure, the anode 401 of each of the second light-emitting devices 42 is connected to the anode 401 of the first light-emitting device 41 adjacent thereto through an anode connecting portion 404, and the anode connecting portion 404 and the anode 401 are located in the same film layer. The vertical projection pattern of the anode connecting portion 404 on the plane of the substrate 10 is a linear structure, and the anode connecting portion 404 and the anodes 401 not connected thereto are insulated from each other.

In an embodiment, the anode 401 of each of the second light-emitting devices 42 is connected to the anode 401 of the first light-emitting device 41 adjacent thereto through the anode connecting portion 404, thereby achieving that the anode 401 of each of the second light-emitting devices 42 is connected to the anode 401 of the first light-emitting device 41 adjacent thereto, and the anode connecting portion 404 and the anode 401 are located in the same film layer, that is, the anode connecting portion 404 and the anode 401 are made of the same material and are formed in the same process step, which is conducive to reducing the process flow and production costs.

The vertical projection pattern of the anode connecting portion 404 on the plane of the substrate 10 is the linear structure, which is conducive to achieving the mutual insulation between the anode connecting portion 404 and the anodes 401 not connected thereto, that is, the anode connecting portion 404 is insulated from the anodes 401 other than the anode 401 connected thereto, thereby achieving the connection of the anode 401 of each of the second light-emitting devices 42 and the anode 401 of the first light-emitting device 41 adjacent thereto through the anode connecting portion 404, while avoiding the anodes 401 of the two light-emitting devices 40 from being connected to the anodes 401 of other light-emitting devices 40, thereby avoiding affecting the display effect.

It should be noted that the vertical projection pattern of the anode connecting portion 404 on the plane of the substrate 10 can be linear, curved, or other linear structures, which can be set according to the arrangement of the light-emitting devices 40, and only need to satisfy the mutual insulation between the anode connection portion 404 and the anodes 401 not connected thereto, which will not be elaborated in the present disclosure.

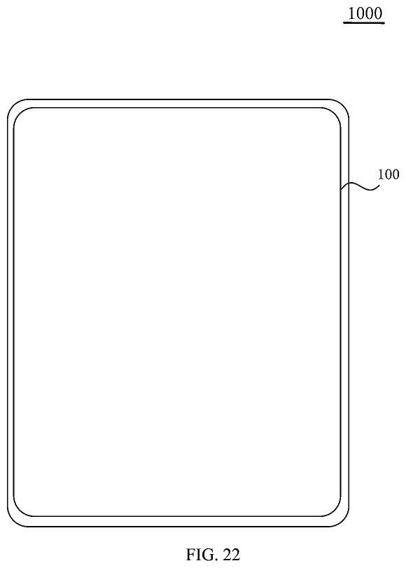

As shown in FIG. 22, FIG. 22 is a schematic plan view of a display apparatus according to some embodiments of the present disclosure. The present disclosure further provides a display apparatus 1000, including the display panel 100 according to any of the above embodiments. The embodiments provided in FIG. 22 only takes a mobile phone as an example to illustrate the display apparatus. It can be understood that the display apparatus according to the embodiments of the present disclosure can be any electronic product with display function, including but not limited to the following categories: mobile phones, televisions, laptops, desktop displays, tablets, digital cameras, smart bracelets, smart glasses, vehicle-mounted displays, medical equipment, industrial control equipment, touch interactive terminals, etc., and the embodiments of the present disclosure do not impose any limitation on the display apparatus.

The display apparatus 1000 according to the embodiments of the present disclosure has the same technical features as the display panel 100 according to the above embodiments, and thus can solve the same technical problem and achieve the same technical effect.

It should be noted that, in the present disclosure, relational terms such as “first” and “second” are only used to distinguish one entity or operation from another entity or operation, and do not necessarily require or imply any actual relationship or order between these entities or operations. Furthermore, terms “include”, “comprise” or any other variants thereof are intended to cover non-exclusive inclusion, so that a process, method, item or device including a series of elements includes not only those elements, but also other elements not explicitly listed, or further includes elements inherent to such process, method, item or device. In the absence of further limitations, the element defined by the sentence “include one . . . ” do not exclude the existence of other identical elements in the process, method, item or device including the elements.

The above description is only specific implementation of the present disclosure, so that those skilled in the art can understand or implement the present disclosure. Various modifications to these embodiments will be apparent to those skilled in the art, and the general principles defined herein can be implemented in other embodiments without departing from the spirit or scope of the present disclosure. Therefore, the present disclosure will not be limited to the embodiments described herein, but will conform to the widest scope consistent with the principles and novel features disclosed herein.

What is claimed is:

1. A display panel, comprising:
a main display area;
a peripheral wiring area surrounding the main display area;
a substrate;
an array layer, wherein the array layer is located on a side of the substrate, and comprises a plurality of pixel driving circuits located in the main display area;
a pixel definition layer, wherein the pixel definition layer is located on a side of the array layer away from the substrate, and comprises a plurality of openings, the plurality of openings comprises first openings and second openings, the first openings are located in the main display area, and the second openings are located in the peripheral wiring area; and
light-emitting devices, wherein the light-emitting devices comprise first light-emitting devices and second light-emitting devices, the first light-emitting devices are in one-to-one correspondence with the first openings and the first light-emitting devices are located in the first openings corresponding thereto, and the second light-emitting devices are in one-to-one correspondence with the second openings and the second light-emitting devices are located in the second openings corresponding thereto,
wherein one of the light-emitting devices comprises an anode, the anode of one of the first light-emitting devices is electrically connected to the pixel driving circuit corresponding thereto, and the anode of one of the second light-emitting devices is connected to the anode of the first light-emitting device adjacent thereto.

2. The display panel according to claim 1, wherein
the light-emitting devices comprise first color light-emitting devices, second color light-emitting devices and third color light-emitting devices, brightness of the first color light-emitting devices is greater than brightness of the second color light-emitting devices, and the brightness of the second color light-emitting devices is greater than brightness of the third color light-emitting devices;
the anode of one of the second light-emitting devices is connected to the anode of the first light-emitting device having a same light-emitting color and adjacent thereto; and/or
the anode of one of the second light-emitting devices is connected to the anode of the first light-emitting device having a different light-emitting color and adjacent thereto.

3. The display panel according to claim 2, comprising a plurality of light-emitting device groups, wherein
one of the light-emitting device groups located in the main display area comprises at least one first color light-emitting device, at least one second color light-emitting device and at least one third color light-emitting device;
one of the light-emitting device groups located in the peripheral display area comprises at least one of the first color light-emitting device, the second color light-emitting device or the third color light-emitting device;
the peripheral wiring area comprises two first wiring areas and two second wiring areas, the two first wiring areas are located on both sides of the main display area along a first direction, respectively, and the two second wiring areas are located on both sides of the main display area along a second direction, respectively, wherein the first direction intersects with the second direction;
one of the first wiring areas comprises at least one column of the light-emitting device groups arranged along the second direction; and
one of the second wiring areas comprises at least one row of the light-emitting device groups arranged along the first direction.

4. The display panel according to claim 3, wherein
the light-emitting device groups comprise first light-emitting device groups, the first light-emitting device groups comprise first light-emitting device sub-groups and second light-emitting device sub-groups arranged along the first direction, one of the first light-emitting device sub-groups comprises one first color light-emitting device and one second color light-emitting device arranged along the second direction, and one of the second light-emitting device sub-groups comprises one third color light-emitting device; and
the light-emitting device groups located in the main display area and the first wiring area are the first light-emitting device groups.

5. The display panel according to claim 4, wherein
the light-emitting device groups located in the second wiring area are the first light-emitting device groups.

6. The display panel according to claim 5, wherein
in two adjacent first light-emitting device sub-groups along the first direction in the second wiring area, the first color light-emitting device and the second color light-emitting device are staggered.

7. The display panel according to claim 4, wherein
the light-emitting device groups comprise second light-emitting device groups, the second light-emitting device groups comprise third light-emitting device sub-groups and fourth light-emitting device sub-groups arranged along the second direction, one of the third light-emitting device sub-groups comprises one first color light-emitting device and one second color light-emitting device arranged along the first direction, and one of the fourth light-emitting device sub-group comprises one third color light-emitting device; and
the light-emitting device groups located in the second wiring area are the second light-emitting device groups, and in the second light-emitting device groups located in the second wiring area, the fourth light-emitting device sub-groups are located on a side of the third light-emitting device sub-groups away from the main display area.

8. The display panel according to claim 3, wherein
the light-emitting device groups comprise third light-emitting device groups, the third light-emitting device groups comprise fifth light-emitting device sub-groups and sixth light-emitting device sub-group arranged along the second direction, one of the fifth light-emitting device sub-groups comprises one first color light-emitting device and one third color light-emitting device arranged along the first direction, and one of the sixth light-emitting device sub-groups comprises one second color light-emitting device;
the fifth light-emitting device sub-groups and the sixth light-emitting device sub-groups in two adjacent third light-emitting device groups along the first direction are staggered; and
the light-emitting device groups located in the main display area and the first wiring area are the third light-emitting device groups.

9. The display panel according to claim 8, wherein
the light-emitting device groups located in the second wiring area are the third light-emitting device groups.

10. The display panel according to claim 8, further comprising a driving chip, wherein
the driving chip is located in the peripheral wiring area, and along the second direction, the driving chip is located on a side of the main display area, and the pixel driving circuits are electrically connected to the driving chip;
the second wiring area comprises a first wiring sub-area, and along the second direction, the first wiring sub-area is located on a side of the main display area away from the driving chip; and
a vertical projection area, of the first color light-emitting devices located in the first wiring sub-area, on a plane of the substrate is smaller than a vertical projection area, of the first color light-emitting devices located in the main display area, on the plane of the substrate.

11. The display panel according to claim 10, wherein
a vertical projection area, of the second color light-emitting devices located in the first wiring sub-area, on the plane of the substrate is greater than a vertical projection area, of the second color light-emitting devices located in the main display area, on the plane of the substrate.

12. The display panel according to claim 8, further comprising a driving chip, wherein
the driving chip is located in the peripheral wiring area, and along the second direction, the driving chip is located on a side of the main display area, and the pixel driving circuits are electrically connected to the driving chip;
the second wiring area comprises a second wiring sub-area, and along the second direction, the second wiring sub-area is located between the main display area and the driving chip; and
a vertical projection area, of the first color light-emitting devices located in the second wiring sub-area, on a plane of the substrate is greater than a vertical projection area, of the first color light-emitting devices located in the main display area, on the plane of the substrate.

13. The display panel according to claim 12, wherein
a vertical projection area, of the second color light-emitting devices located in the second wiring sub-area, on the plane of the substrate is smaller than a vertical projection area, of the second color light-emitting devices located in the main display area, on the plane of the substrate.

14. The display panel according to claim 3, wherein
one of the light-emitting device groups located in the peripheral display area comprises one light-emitting device.

15. The display panel according to claim 1, wherein
a vertical projection area, of the second light-emitting devices, on a plane of the substrate is greater than a vertical projection area, of the first light-emitting devices, on the plane of the substrate.

16. The display panel according to claim 1, wherein
a distance between two adjacent second light-emitting devices is greater than a distance between two adjacent first light-emitting devices.

17. The display panel according to claim 1, wherein
the anode of one of the second light-emitting devices is connected to the anode of the first light-emitting device adjacent thereto through an anode connecting portion, and the anode connecting portion and the anode are located in a same film layer; and
a vertical projection pattern of the anode connecting portion on a plane of the substrate is a linear structure, and the anode connecting portion and the anodes not connected thereto are insulated from one another.

18. A display apparatus, comprising a display panel, wherein the display panel comprises:
a main display area;
a peripheral wiring area surrounding the main display area;
a substrate;
an array layer, wherein the array layer is located on a side of the substrate, and comprises a plurality of pixel driving circuits located in the main display area;
a pixel definition layer, wherein the pixel definition layer is located on a side of the array layer away from the substrate, and comprises a plurality of openings, the plurality of openings comprise first openings and second openings, the first openings are located in the main display area, and the second openings are located in the peripheral wiring area; and
light-emitting devices, wherein the light-emitting devices comprise first light-emitting devices and second light-emitting devices, the first light-emitting devices are in one-to-one correspondence with the first openings and the first light-emitting devices are located in the first openings corresponding thereto, and the second light-emitting devices are in one-to-one correspondence with the second openings and the second light-emitting devices are located in the second openings corresponding thereto,
wherein one of the light-emitting devices comprises an anode, the anode of one of the first light-emitting devices is electrically connected to the pixel driving circuit corresponding thereto, and the anode of one of the second light-emitting devices is connected to the anode of the first light-emitting device adjacent thereto.
